(19) United States
(12) Patent Application Publication
(10) Pub. No.: US 2019/0068847 A1
(43) Pub. Date: Feb. 28, 2019

(54) OPTICAL SENSOR AND IMAGING APPARATUS

(71) Applicant: SUMITOMO ELECTRIC INDUSTRIES, LTD., Osaka (JP)

(72) Inventor: Hiroshi OBI, Osaka-shi (JP)

(73) Assignee: SUMITOMO ELECTRIC INDUSTRIES, LTD., Osaka (JP)

(21) Appl. No.: 16/107,313

(22) Filed: Aug. 21, 2018

(30) Foreign Application Priority Data
Aug. 23, 2017 (JP) 2017-160143

(51) Int. Cl. H04N 5/225; H05K 5/06; H05K 5/02; H05K 1/11; H01L 27/146

(52) U.S. Cl. CPC H04N 5/2252; H05K 5/069; H05K 5/0247; H05K 1/111; H05K 2201/10151; H01L 27/14618; H01L 27/14636; H04N 5/2253; H05K 2201/10121; H01L 27/14634

(57) ABSTRACT

An optical sensor includes an image sensor device that converts an incident-light image into an electric image signal, and a case that hermetically houses the image sensor device. The case has an entrance window that transmits the incident-light image, and a feedthrough allowing an inside and an outside of the case to be electrically conductive to each other. The feedthrough includes an insulating member forming part of the case, a deformation-easing member positioned on an outer side with respect to the insulating member, and a plurality of plate-like conductors each extending through the insulating member and the deformation-easing member. The deformation-easing member is easier to deform than the insulating member.

### BACKGROUND OF THE INVENTION

### 1. Field of the Invention

The present invention relates to an optical sensor and an imaging apparatus.

### 2. Description of the Related Art

In Japanese Unexamined Patent Application Publication No. 2011-96921, a light-receiving-device array in which light-receiving devices made of a compound semiconductor that is sensitive to light of the near-infrared range are arranged, and a detecting device including the light-receiving-device array are disclosed. According to Japanese Unexamined Patent Application Publication No. 2011-96921, to suppress the occurrence of dark currents in the light-receiving devices, light-receiving devices are used at a temperature of −40° C. to the liquid-nitrogen temperature (−196° C.). In a case where light-receiving devices are cooled for use, the light-receiving devices are housed in a hermetically sealed case, whereby the devices are kept out of contact with the atmosphere. The inside of the case is set to a vacuum or is filled with an inert gas. To electrically connect the inside and the outside of such a hermetic case, the case has a feedthrough. The feedthrough includes an insulating member forming part of the case, and conductors each extending through the insulating member and transmitting an electric signal. In such a known feedthrough, a plurality of plate-like conductors are arranged side by side in a predetermined direction and such that surfaces of the respective conductors are flush with one another in a specific virtual plane. Hence, it is easy to conductively bond electric wires on a circuit board provided outside the case to the plurality of conductors.

### SUMMARY OF THE INVENTION

However, when the circuit board provided outside the case and the plurality of conductors included in the feedthrough are bonded to each other with conductive adhesive, a force is applied to the conductors and generates a stress near a hole provided for the insulating member to pass therethrough. Even after the plurality of conductors and the circuit board are bonded to each other, a similar stress occurs in the insulating member through the conductors if any external force is applied to the circuit board. Such a stress may make a crack in the insulating member, making it difficult to keep the case hermetic.

The present invention has been conceived in view of the above problem and provides an optical sensor and an imaging apparatus in which the occurrence of a crack in an insulating member included in a feedthrough provided to a package that houses an image sensor therein is suppressed.

To solve the above problem, according to an aspect of the present invention, there is provided an optical sensor including an image sensor device that converts an incident-light image into an electric image signal, and a case that hermetically houses the image sensor device. The case has an entrance window that faces the image sensor device and transmits the incident-light image; and a feedthrough that includes an insulating member forming part of the case, and a plurality of plate-like conductors each extending through the insulating member and arranged side by side in a predetermined direction, the feedthrough allowing an inside and an outside of the case to be electrically conductive to each other. The feedthrough further includes a deformation-easing member that is bonded to the insulating member while covering part of each of the conductors that is positioned on an outer side with respect to the insulating member.

### BRIEF DESCRIPTION OF THE DRAWINGS

FIG. 1 is a block diagram schematically illustrating a configuration of an imaging apparatus according to an embodiment.

FIG. 2 is an external perspective view of an optical sensor according to the embodiment.

FIG. 3 is a front view of the optical sensor.

FIG. 4 is a sectional view of part of the optical sensor that is taken along line Iv-Iv illustrated in FIG. 2.

FIG. 5 is a schematic sectional view of a mount, an image sensor device, and peripheral elements.

FIG. 6A is an enlarged perspective view of a feedthrough and peripheral elements.

FIG. 6B is an enlargement of a part B encircled in FIG. 6A.

FIG. 7 is an enlarged sectional view of part of the feedthrough that is near an outer surface thereof and peripheral elements.

FIG. 8 is an enlarged sectional view of part of a feedthrough that is near an outer surface thereof and peripheral elements included in an optical sensor according to a first modification.

FIG. 9 is an enlarged sectional view of part of a feedthrough that is near an outer surface thereof and peripheral elements included in an optical sensor according to a second modification.

FIG. 9 is an enlarged sectional view of part of a feedthrough that is near an outer surface thereof and peripheral elements included in an optical sensor according to a second modification.

FIG. 10 is an enlarged sectional view of part of a feedthrough that is near an outer surface thereof and peripheral elements included in an optical sensor according to a third modification.

FIG. 11 is an enlarged sectional view of part of a feedthrough that is near an outer surface thereof and peripheral elements included in an optical sensor according to a fourth modification.

FIG. 12 is an enlarged sectional view of part of a feedthrough that is near an outer surface thereof and peripheral elements included in an optical sensor according to a fifth modification.

FIG. 13 is an enlarged sectional view of part of a feedthrough that is near an outer surface thereof and peripheral elements according to another example of the fifth modification.

FIG. 14A is an enlarged perspective view of a feedthrough and peripheral elements included in an optical sensor according to a sixth modification.

FIG. 14B is an enlarged side view of part of the feedthrough according to the sixth modification.

FIG. 15A is an enlarged perspective view of a feedthrough and peripheral elements included in an optical sensor according to a comparative example.

FIG. 15B is an enlargement of a part C encircled in FIG. 15A.

### DESCRIPTION OF THE PREFERRED EMBODIMENTS

### Description of Embodiments of the Invention

Embodiments of the present invention will be outlined first. An optical sensor includes an image sensor device that converts an incident-light image into an electric image signal, and a case that hermetically houses the image sensor device. The case has an entrance window that faces the image sensor device and transmits the incident-light image; and a feedthrough that includes an insulating member forming part of the case, and a plurality of plate-like conductors each extending through the insulating member and arranged side by side in a predetermined direction, the feedthrough allowing an inside and an outside of the case to be electrically conductive to each other. The feedthrough further includes a deformation-easing member that is bonded to the insulating member while covering part of each of the conductors that is positioned on an outer side with respect to the insulating member, the deformation-easing member being easier to deform than the insulating member.

In the optical sensor, the part of each of the conductors that is on the outside with respect to the insulating member is covered with the deformation-easing member that is easier to deform than the insulating member. The deformation-easing member is bonded to the insulating member. Therefore, if any force is applied to the conductors, the deformation-easing member receives a corresponding stress and disperses the stress over the insulating member. Thus, the occurrence of local stress in the insulating member can be suppressed, and the occurrence of a crack in the insulating member can be suppressed.

In the above optical sensor, the insulating member may include at least one of glass and ceramic, and the deformation-easing member may include resin. With such a combination of materials, the deformation-easing member can be made easier to deform than the insulating member.

In the above optical sensor, the deformation-easing member may have an insulating characteristic. In such a case, adjacent ones of the conductors can be easily kept insulated from each other.

In the above optical sensor, the insulating member may form a bottom surface of a recess provided in an outer surface of the case, and at least part of the deformation-easing member may fill the recess. In such a case, the bonding strength between the insulating member and the deformation-easing member increases, and peeling of the deformation-easing member from the insulating member that may occur when the conductors are bent can be suppressed. Thus, the reliability of the optical sensor can be increased. Furthermore, since the presence of the recess in the insulating member suppresses the movement of the deformation-easing member, bending of the conductors at the application of any force to the conductors can be suppressed.

In the above optical sensor, the plurality of conductors may each have a rectangular sectional shape. In such a case, stress occurring in the insulating member tends to concentrate on regions of the insulating member that are near the corners of the rectangular conductors, and cracks tend to occur in such regions of the insulating member. Therefore, the above optical sensor effectively works.

An imaging apparatus according to another embodiment includes the optical sensor having any of the above features, a circuit board having wire pads that are electrically connected to an end of each of the plurality of conductors that is positioned on the outside of the case, and a signal processor that converts an electrical signal obtained from the signal processor into an image signal. With the imaging apparatus, since the optical sensor having any of the above features is included, the occurrence of a crack in the insulating member can be suppressed.

### Details of a Specific Embodiment of the Invention

An optical sensor and an imaging apparatus according to a specific embodiment of the present invention will now be described with reference to the drawings. The present invention is not limited to the following embodiment. The scope of the present invention is defined by the appended claims and is intended to encompass all equivalents thereof and all modifications thereof made within the scope. In the following description given with reference to the drawings, like reference numerals denote like elements, and redundant description is omitted.

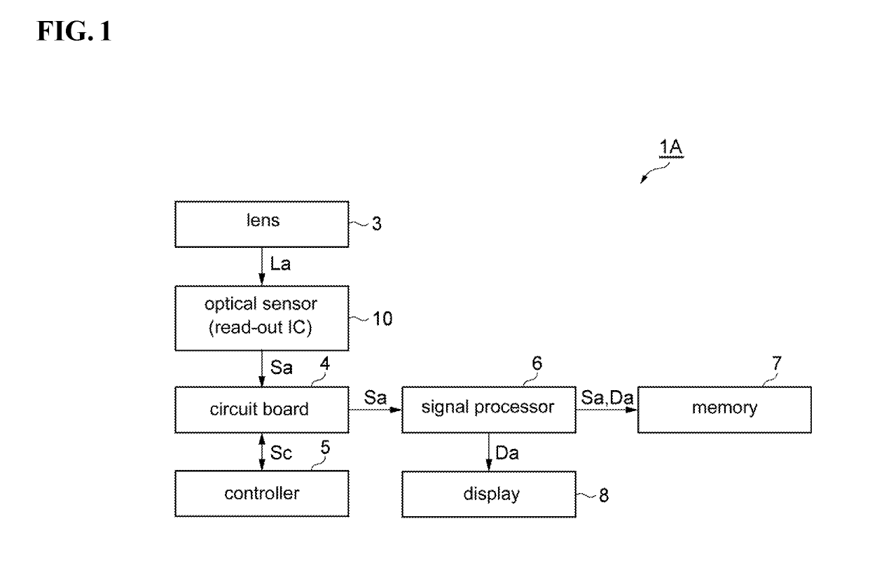

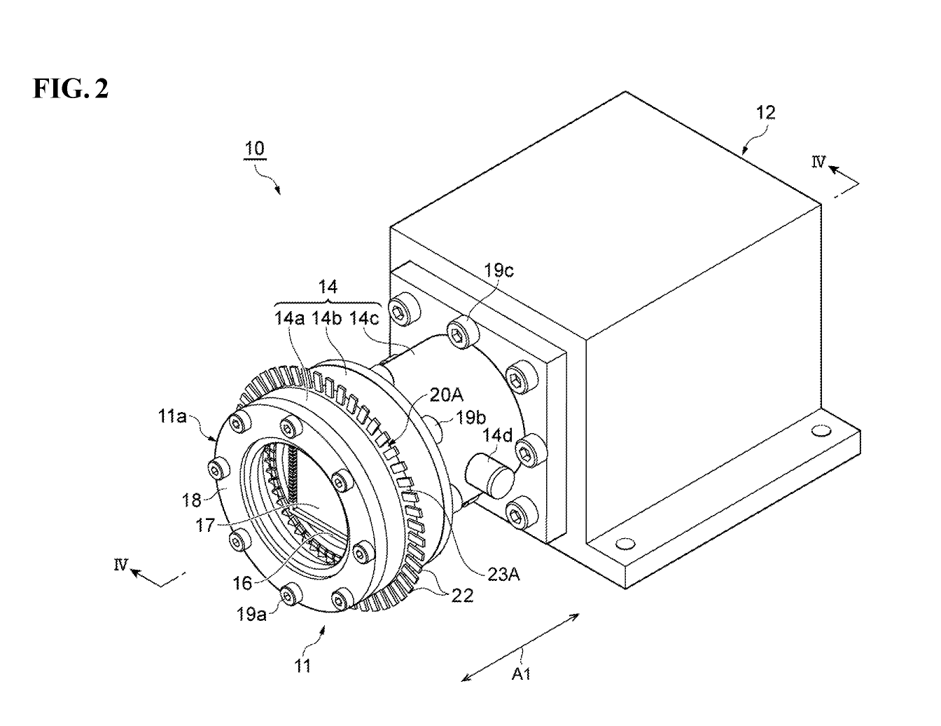

FIG. 1 is a block diagram schematically illustrating a configuration of an imaging apparatus 1A according to an embodiment. As illustrated in FIG. 1, the imaging apparatus 1A according to the present embodiment includes a lens 3, an optical sensor 10 including a control integrated circuit (IC), a circuit board 4, a controller 5, a signal processor 6, a memory 7, and a display 8. The optical sensor 10 includes an image sensor device 17 (see FIG. 2) that converts incident-light image La into an electric image signal Sa, the control IC that controls the operation of the image sensor device 17, and a case 11a (see FIG. 2) that hermetically houses the image sensor device 17 and the control IC. The lens 3 is a condenser lens and is provided in such a manner as to face the image sensor device 17. The lens 3 focuses the incident-light image La on the image sensor device 17. The incident-light image La is an infrared-ray image with a wave range of, for example, 0.7 μm to 1000 μm.

The circuit board 4 is a printed circuit board including a base substrate made of, for example, glass epoxy. The circuit board 4 includes a plurality of wiring pad arranged on a surface of the base substrate. The wiring pads of the circuit board 4 is electrically connected to the optical sensor 10. The circuit board 4 transmits the image signal Sa, which is outputted from the image sensor device 17, to the signal processor 6. The circuit board 4 has a wiring board and electronic components such as the control IC mounted on the wiring board. The circuit board 4 receives a control signal Sc from the controller 5 and controls the transmission of the image signal Sa to the signal processor 6. The signal processor 6 converts the image signal Sa received from the circuit board 4 into image data Da. The controller 5 and the signal processor 6 are each, for example, a large-scale integrated circuit including many logic circuits integrated together, or a computer including a central processing unit and a memory and that operates in accordance with a predetermined program. The memory 7 stores at least one of the image signal Sa outputted from the circuit board 4 and the image data Da generated by the signal processor 6. The display 8 receives the image data Da from the signal processor 6 and displays the image data Da on a screen thereof.

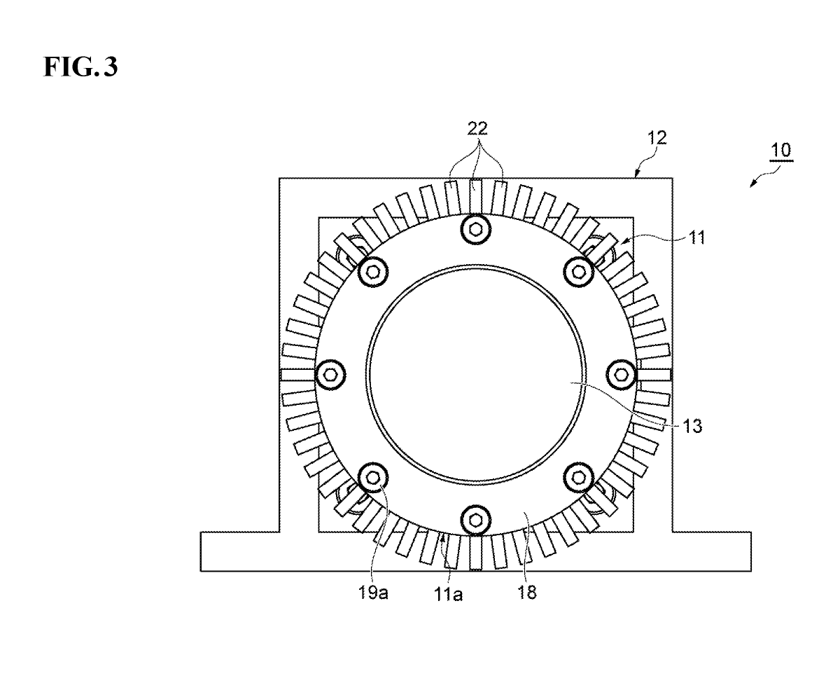

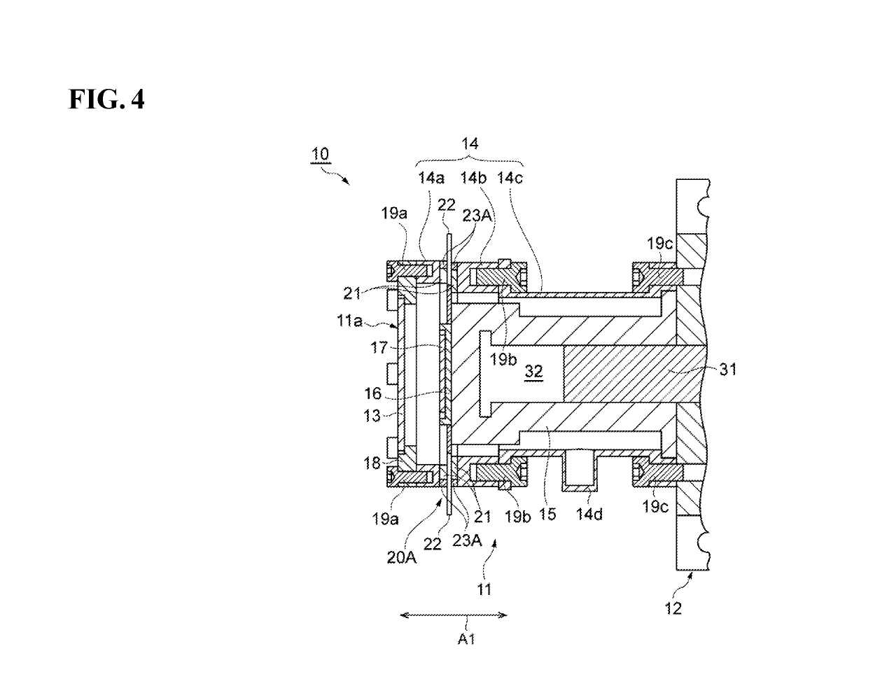

FIG. 2 is an external perspective view of the optical sensor 10 according to the embodiment. FIG. 3 is a front view of the optical sensor 10. FIG. 4 is a sectional view of part of the optical sensor 10 that is taken along line Iv-Iv illustrated in FIG. 2. As illustrated in FIGS. 2 to 4, the optical sensor 10 according to the present embodiment includes a body 11 and a small cooler 12. The body 11 includes an entrance window 13 (not illustrated in FIG. 2), a hermetically sealed housing 14, a head 15, a mount 16, the image sensor device 17, a frame 18, and a feedthrough 20A. The entrance window 13, the hermetically sealed housing 14, the frame 18, and the feedthrough 20A together form the case 11a that houses the image sensor device 17.

As shown in FIGS. 2 and 4, the feedthrough 20A includes a plurality of plate-like conductors 22, and a deformation-easing member 23A. The feedthrough 20A also includes an insulating member 21 adjacent to the deformation-easing member 23A. As for the electrical connection of the circuit board 4 and the optical sensor 10, the circuit board 4 is provided on the left side of the optical sensor 10 in a specific direction A1 in FIG. 2. The circuit board 4 has a hole with a diameter larger than the diameter of the hermetically sealed housing 14. The plurality of wire pads are provided on the surface of the circuit board 4, and are arranged along the periphery of the hole. The plurality of wire pads are electrically connected to a plurality of electric components, such as the control IC, respectively, mounted on the circuit board 4. The circuit board 4 and the optical sensor 10 are arranged such that the entrance window 13 of the body 11 is exposed from the hole of the circuit board 4. A virtual plane in which the plurality of plate-like conductors 22 of the optical sensor 10 extends and a virtual plane in which the wire pads of the circuit board 4 are arranged are positioned close to each other and substantially parallel to each other. One side of the plurality of plate-like conductors 22 and surfaces of the respective wiring pads of the circuit board 4 are electrically and physically connected to each other with, for example, solder. After the feedthrough 20A and the wiring board are physically fixed to each other, any external force may be applied thereto. In such a situation, the parallelism between the virtual plane of the plurality of plate-like conductors 22 and the virtual plane of the plurality of plate-like conductors 22 may be lost. Consequently, undesirable stress may occur in the feedthrough 20A.

The entrance window 13 is a plate-like member that transmits the incident-light image La. The entrance window 13 is positioned in such a manner as to face the image sensor device 17 to be described below. The material of the entrance window 13 is determined in accordance with the wavelength of the incident-light image La. For example, if the wavelength of the incident-light image La is 1.2 μm to 6 μm, silicon is selected as the material of the entrance window 13. Seen in an incoming direction of the incident-light image La, the entrance window 13 has a circular shape. The entrance window 13 is provided on the peripheral edge thereof with the frame 18, which has an annular shape and holds the entrance window 13. The frame 18 is made of metal, for example. The frame 18 and the entrance window 13 are closely attached to each other so that the hermetic state is maintained.

The hermetically sealed housing 14 has a substantially cylindrical appearance extending in the specific direction A1. The hermetically sealed housing 14 is made of metal such as stainless steel. The outer peripheral surface of the hermetically sealed housing 14 forms the outer peripheral surface of the body 11. The hermetically sealed housing 14 is provided at one end thereof in the direction A1 with the frame 18 hermetically fixed thereto while holding the entrance window 13. Hence, an opening of the hermetically sealed housing 14 that is provided on one side in the direction A1 is closed by the entrance window 13. The direction A1 coincides with the thickness direction of the entrance window 13. That is, the direction A1 coincides with the incoming direction of the incident-light image La.

More specifically, the hermetically sealed housing 14 includes an annular first member 14a, an annular second member 14b, and a substantially cylindrical third member 14c. The first member 14a and the second member 14b are arranged side by side in the direction A1 between the third member 14c and the frame 18. Seen in the direction A1, the first member 14a, the second member 14b, and the third member 14c overlap one another. That is, spaces on the inner side of the first member 14a, the second member 14b, and the third member 14c are continuous with one another in the direction A1. The frame 18 is fastened to one end surface of the first member 14a with fastening members 19a such as bolts. The gap between the frame 18 and the first member 14a is hermetically sealed. One end surface of the third member 14c is fastened to one end surface of the second member 14b with fastening members 19b such as bolts. The gap between the second member 14b and the third member 14c is hermetically sealed. The other end surface of the third member 14c is fastened to the small cooler 12 with fastening members 19c such as bolts. The gap between the third member 14c and the small cooler 12 is hermetically sealed. The feedthrough 20A is held between the other end surface of the first member 14a and the other end surface of the second member 14b. In other words, the first member 14a and the second member 14b are joined to each other with the feedthrough 20A interposed therebetween.

One tube 14d for vacuuming projects from the outer surface of the third member 14c. The tube 14d communicates with the space inside the hermetically sealed housing 14. After the inside of the hermetically sealed housing 14 is vacuumed through the tube 14d (or after the space is filled with an inert gas), the end of the tube 14d is hermetically sealed.

The head 15 is a substantially cylindrical metal member provided in the hermetically sealed housing 14 and extending in the direction A1. The outer peripheral surface of the head 15 faces the inner peripheral surface of the hermetically sealed housing 14 with an air gap interposed therebetween. The air gap is kept in a vacuum state or is filled with an inert gas. One end of the head 15 in the direction A1 is closed, while the other end of the head 15 is fixed to the small cooler 12. The head 15 has an opening at the other end thereof, and a piston 31 is inserted into the opening. The head 15 has a space 32 thereinside extending from the opening. With a reciprocating motion of the piston 31 in the direction A1, the volume of the space 32 increases and decreases repeatedly. The space 32 is filled with a helium gas. With the changes in the volume of the space 32, the temperature inside the head 15 changes. The one end of the head 15 in the direction A1 forms a flat surface intersecting the direction A1, and the mount 16 is provided on the flat surface.

The mount 16 is a plate-like member on which the image sensor device 17 is mounted. Seen in the direction A1, the mount 16 has a quadrilateral shape. A surface of the mount 16 that is on one side is joined to the flat surface of the head 15. A surface of the mount 16 that is on the other side has a recess in which the image sensor device 17 is fitted. The mount 16 is made of ceramic such as aluminum nitride. The mount 16 fixes the image sensor device 17 with respect to the head 15 and thermally coupling the image sensor device 17 and the head 15 to each other.

The image sensor device 17 is a semiconductor device that converts the incident-light image La into the electric image signal Sa. The image sensor device 17 is mainly made of a semiconductor material such as indium gallium arsenide (InGaAs) and is an infrared sensor array that is sensitive to light having any wavelength between 0.9 μm and 1.7 μm. The image sensor device 17 is hermetically housed in the case 11a that is formed of the entrance window 13, the hermetically sealed housing 14, the head 15, the frame 18, and the feedthrough 20A. Seen in the direction A1, the image sensor device 17 has, for example a quadrilateral plan-view shape, which is similar to the plan-view shape of the mount 16.

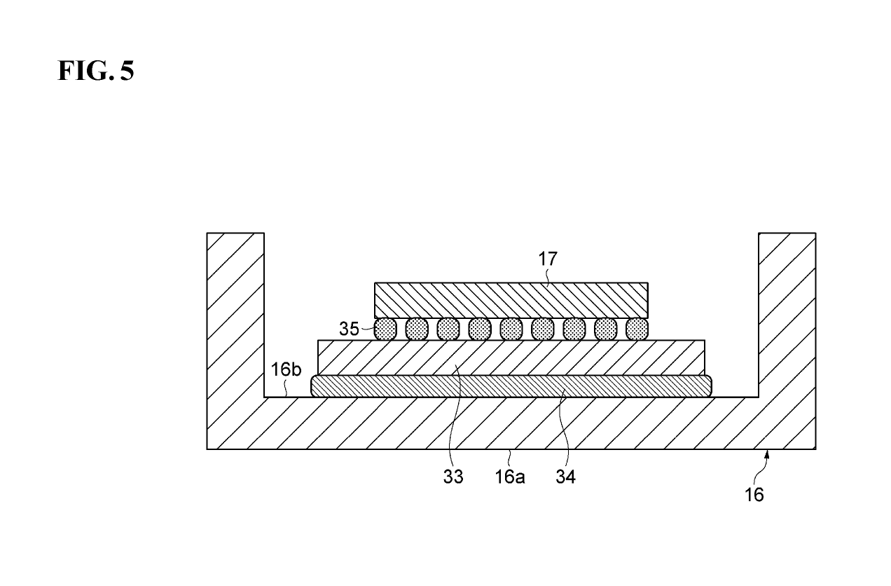

FIG. 5 is a schematic sectional view of the mount 16, the image sensor device 17, and peripheral elements. As illustrated in FIG. 5, the mount 16 has a back surface 16a that faces the head 15, and a mounting surface 16b opposite the back surface 16a. The mounting surface 16b forms a bottom surface of the recess. The mounting surface 16b carries a control IC 33. The image sensor device 17 is mounted on the control IC 33. The control IC 33 is fixed to the mounting surface 16b with conductive adhesive 34, such as silver paste, interposed therebetween. The image sensor device 17 is electrically connected to the control IC 33 with a plurality of bump electrodes 35 provided on the back surface thereof opposite an incident surface that receives light. The control IC 33 has a plurality of terminals for transmitting and receiving signals to and from the circuit board 4. The terminals are connected, with bonding wires, to a plurality of terminals, respectively, provided on the mount 16. The terminals of the mount 16 are connected to the feedthrough 20A with bonding wires, respectively. The plurality of terminals of the mount 16 extend from the inside of the recess of the mount 16 to the edge of the mount 16.

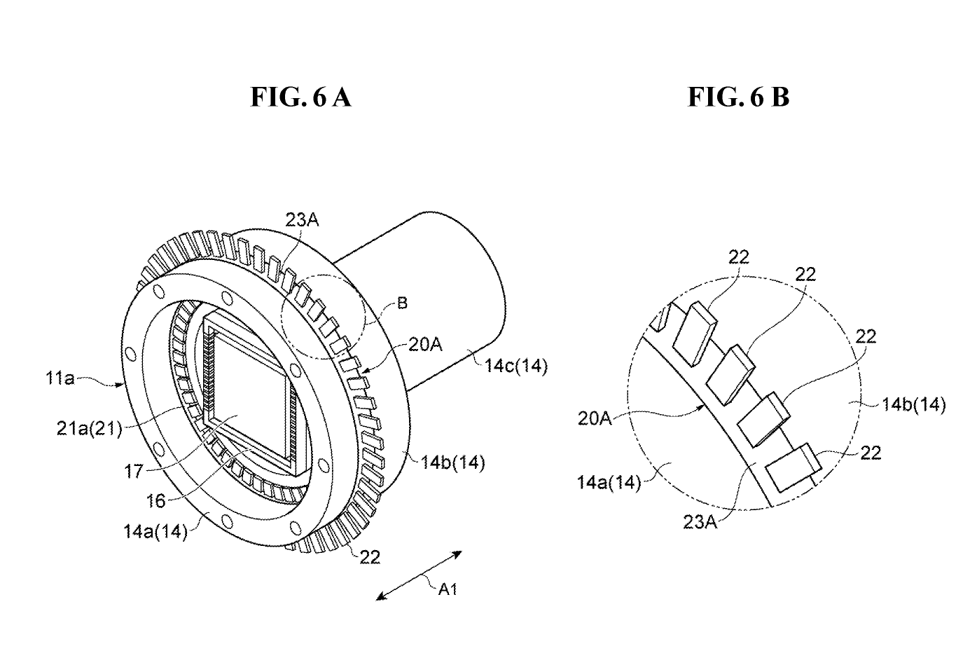

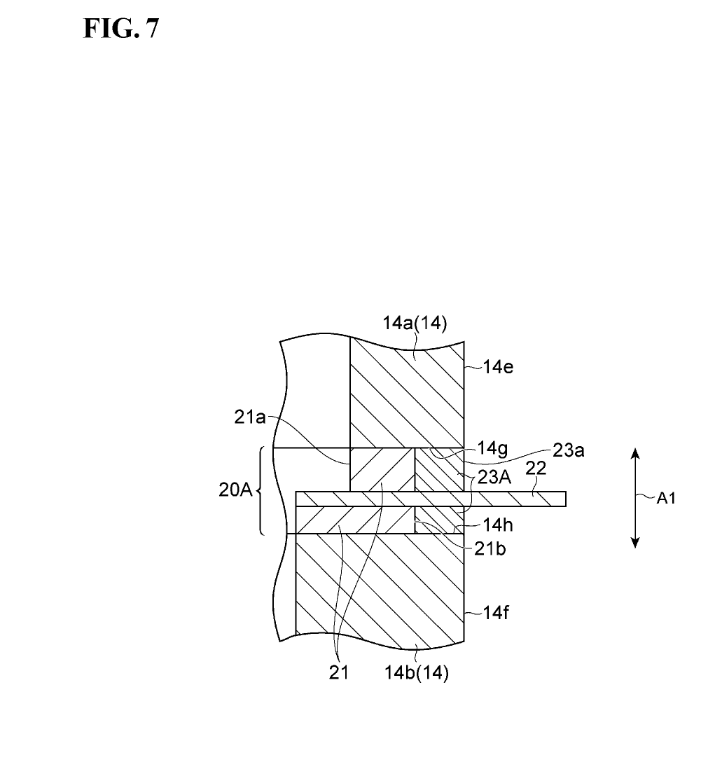

Now, the feedthrough 20A will be described in detail. FIG. 6A is an enlarged perspective view of the feedthrough 20A and peripheral elements. In FIG. 6A, the entrance window 13 and the frame 18 are not illustrated. FIG. 6B is an enlargement of a part B encircled in FIG. 6A. FIG. 7 is an enlarged sectional view, taken in the direction A1, of part of the feedthrough 20A that is near an outer surface thereof and peripheral elements.

As illustrated in FIG. 6A, the feedthrough 20A is a structural member for allowing the control IC 33 provided inside the case 11a and the circuit board 4 provided outside the case 11a to be electrically conductive to each other. A diameter of the case 11a is 15 millimeter. As illustrated in FIG. 7, the feedthrough 20A includes an insulating member 21, a plurality of plate-like conductors 22, and a deformation-easing member 23A. The insulating member 21 is an annular member that shares the center axis with the first member 14a and the second member 14b of the hermetically sealed housing 14. The insulating member 21 forms part of the case 11a that houses the image sensor device 17. The insulating member 21 has an inner surface 21a facing the inside of the case 11a, and an outer surface 21b (see FIG. 7) facing the outside of the case 11a, thereby separating the inside and the outside of the case 11a from each other. The insulating member 21 is made of an insulating material such as glass or ceramic, in view of electrical insulation and airtightness. The materials are selected in accordance with pressure resistance and heat resistance required for the feedthrough 20A. The insulating member 21 according to the present embodiment mainly includes at least one of glass and ceramic.

The plurality of conductors 22 are conductive members made of, for example, metal such as stainless steel (or an alloy if high hardness is required) plated with gold. The plurality of conductors 22 each have a plate-like shape and extend through the inner surface 21a and the outer surface 21b of the insulating member 21. The plurality of conductors 22 are arranged side by side in the peripheral direction of the insulating member 21 (the predetermined direction according to the present embodiment). In the peripheral direction, the plurality of conductors 22 are arranged at regular intervals and over the entire periphery. One of two ends of each of the conductors 22 that is positioned inside the case 11a is electrically connected to a corresponding one of the plurality of terminals of the mount 16 with a bonding wire interposed therebetween. The other end of the conductor 22 that is positioned outside the case 11a is conductively connected to the circuit board 4 with conductive adhesive such as solder. The circuit board 4 has a circular hole in which the body 11 is fitted, thereby being in contact with the plurality of conductors 22. The number of the conductors 22 is, for example, 48. Each conductor 22 has a width of 1 millimeter in the peripheral direction, and has a thickness of 0.3 millimeters. Each conductor 22 protrudes from the deformation-easing member 23A by 3 millimeters.

The conductor 22 has a plate-like shape whose longitudinal direction intersects the outer surface 21b, and has a pair of surfaces that are opposite each other. The pair of surfaces extend parallel to each other and along the periphery of the insulating member 21 (in a direction in which the plurality of conductor 22 are arranged side by side). Portions of the plurality of conductor 22 that are positioned inside the case 11a are side by side in the peripheral direction of the insulating member 21. On the inside of the case 11a, the surfaces of the conductors 22 are flush with one another in a specific virtual plane. Portions of the plurality of conductors 22 that are positioned outside the case 11a are also side by side in the peripheral direction of the insulating member 21. On the outside of the case 11a, the surfaces of the conductors 22 are also flush with one another in the virtual plane.

As illustrated in FIG. 7, the outer surface 21b of the insulating member 21 is positioned nearer to the inner surface 21a than an outer surface 14e of the first member 14a and an outer surface 14f of the second member 14b. That is, the outer surface 21b of the insulating member 21 forms a bottom surface of a recess provided in the outer surface of the case 11a. The recess is defined by an end surface 14g of the first member 14a, an end surface 14h of the second member 14b, and the outer surface 21b. The end surfaces 14g and 14h face each other in the direction A1. In the present embodiment, the end surfaces 14g and 14h are flat surfaces that are perpendicular to the direction A1 and to the outer surface 21b and are parallel to each other. A distance between the surfaces 14g and 14h is 4 millimeters, and a depth of the recess in a direction perpendicular to the direction A1 is 2 millimeters. A distance between the surface 14g and an upper surface of the conductor 22 is 2 millimeters, and a distance between the surface 14h and a lower surface of the conductor 22 is 1.7 millimeters. The recess is filled with the deformation-easing member 23A.

The deformation-easing member 23A is provided on the outer surface 21b of the insulating member 21. The deformation-easing member 23A covers part of each of the conductors 22 that is on the outer side of the insulating member 21 (part of the conductor 22 that is exposed from the insulating member 21). Note that the outer end of each of the conductors 22 is exposed on the outer side of the deformation-easing member 23A. The deformation-easing member 23A fills the recess defined by the end surface 14g of the first member 14a, the end surface 14h of the second member 14b, and the outer surface 21b of the insulating member 21 and is bonded to the end surface 14g, the end surface 14h, and the outer surface 21b.

The deformation-easing member 23A is made of a material that is easier to deform than the insulating member 21 (that is, the deformation-easing member 23A has a smaller Young's modulus than the insulating member 21). The deformation-easing member 23A mainly includes resin, for example. The resin may be epoxy resin having relatively high hardness, or silicon resin having relatively low hardness. The deformation-easing member 23A has an insulating characteristic. An outer surface 23a of the deformation-easing member 23A that is farther from the insulating member 21 extends in the direction A1. That is, in a section perpendicular to the direction of arrangement of the conductors 22, the outer surface 23a extends linearly in the direction A1. The conductors 22 project from the outer surface 23a in a direction perpendicular to the outer surface 23a.

Referring to FIG. 7, the wire pads of the wiring board (not illustrated) are provided close to, for example, the upper surfaces of the conductors 22 of the feedthrough 20A. The feedthrough 20A is physically fixed to the wire pads with solder and is electrically connected thereto. After the feedthrough 20A and the wire pads are fixed to each other with solder, any external force may displace the wiring board relative to the feedthrough 20A. In such a situation, the conductors 22 may be individually pushed and/or pulled by the wiring board with the solder interposed therebetween. Consequently, an undesirable stress occurs at the bases of the conductors 22, i.e., at the points of contact between the conductors 22 and the deformation-easing member 23A. The deformation-easing member 23A according to the present embodiment is easy to deform. Since the deformation-easing member 23A deforms with the stress, concentration of the stress on the bases of the conductors 22 can be avoided. Therefore, the deformation-easing member 23A is less likely to be damaged.

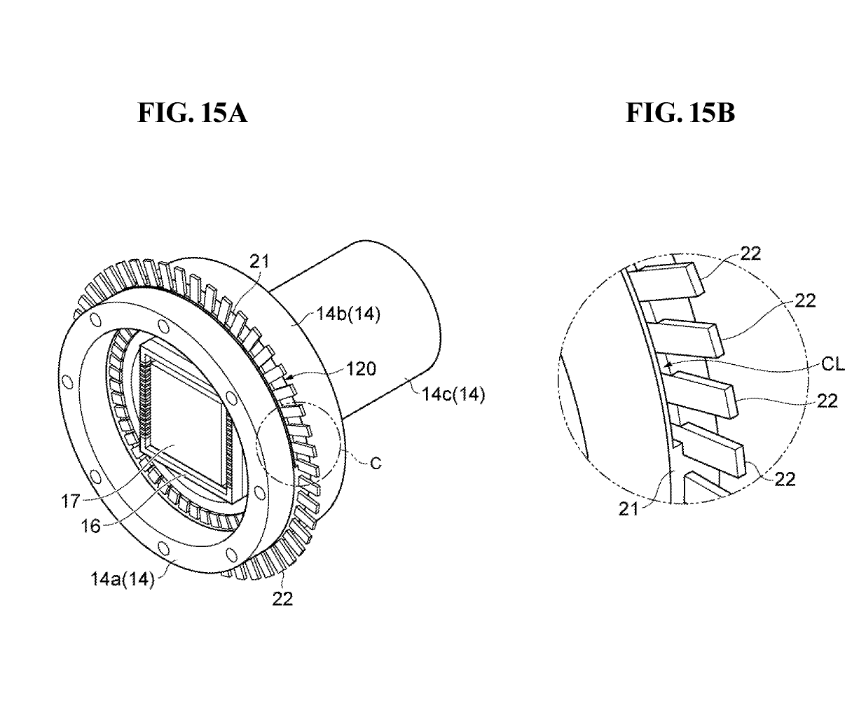

Advantageous effects brought by the imaging apparatus 1A and the optical sensor 10 according to the present embodiment will now be described, in association with a problem in the related art. FIG. 15A is an enlarged perspective view of a feedthrough 120 and peripheral elements included in an optical sensor according to a comparative example. In FIG. 15A, an entrance window 13 and a frame 18 are not illustrated. FIG. 15B is an enlargement of a part C encircled in FIG. 15A. As illustrated in FIGS. 15A and 15B, in the feedthrough 120, a plurality of plate-like conductors 22 are arranged side by side in a predetermined direction, and the surfaces of the conductors 22 are flush with one another in a specific virtual plane. Hence, it is easy to conductively bond a circuit board 4 and the plurality of conductors 22 to each other.

However, when the circuit board 4 and the plurality of conductors 22 are bonded to each other with conductive adhesive, a force is applied to the conductors 22 and generates a stress near a hole provided in an insulating member 21 for the conductors 22 to pass therethrough. Even after the plurality of conductors 22 and the circuit board 4 are bonded to each other, a similar stress occurs in the insulating member 21 through the conductors 22 if any external force is applied to the circuit board 4. Such a stress may make a crack CL in the insulating member 21, making it difficult to keep the case hermetic. According to the knowledge of the present inventor, the crack CL occurring in the insulating member 21 of the feedthrough 120 tends to develop from the interface between the plate-like conductor 22 and the insulating member 21 and along a plane perpendicular to the stress occurring in the interface. In the feedthrough 120 in which surfaces of the plurality of plate-like conductors 22 are flush with one another in a specific virtual plane, the planes perpendicular to stresses occurring in adjacent ones of the plate-like conductors 22 overlap each other. Therefore, a crack CL is more likely to occur.

In view of the above problem, the optical sensor 10 according to the present embodiment is configured such that part of each of the conductors 22 that is on the outer side with respect to the insulating member 21 is covered with the deformation-easing member 23A that is easier to deform than the insulating member 21. Furthermore, the deformation-easing member 23A is bonded to the insulating member 21. Therefore, if any force is applied to the conductors 22, the deformation-easing member 23A receives a corresponding stress and disperses the stress over the insulating member 21. Hence, with the imaging apparatus 1A and the optical sensor 10 according to the present embodiment, the occurrence of local stress in the insulating member 21 can be suppressed, and the occurrence of a crack in the insulating member 21 can be suppressed.

As in the present embodiment, the insulating member 21 may include at least one of glass and ceramic, and the deformation-easing member 23A may include resin. With such a combination of materials, the deformation-easing member 23A can be made easier to deform than the insulating member 21.

As in the present embodiment, the deformation-easing member 23A may have an insulating characteristic. In such a case, adjacent ones of the conductors 22 can be easily kept insulated from each other.

As in the present embodiment, the insulating member 21 may form the bottom surface of the recess provided in the outer surface of the case 11a, and at least part of the deformation-easing member 23A may fill the recess. In such a case, the bonding strength between the insulating member 21 and the deformation-easing member 23A increases, and peeling of the deformation-easing member 23A from the insulating member 21 that may occur when the conductors 22 are bent can be suppressed. Thus, the reliability of the optical sensor 10 can be increased. Furthermore, since the presence of the recess in the insulating member 21 suppresses the movement of the deformation-easing member 23A, bending of the conductors 22 at the application of any force to the conductors 22 can be suppressed.

As in the present embodiment, the plurality of conductors 22 may each have a rectangular sectional shape. In such a case, stress occurring in the insulating member 21 tends to concentrate on regions of the insulating member 21 that are near the corners of the rectangular conductors 22, and cracks CL tend to occur in such regions of the insulating member 21. Therefore, the optical sensor 10 according to the present embodiment effectively works.

### First Modification

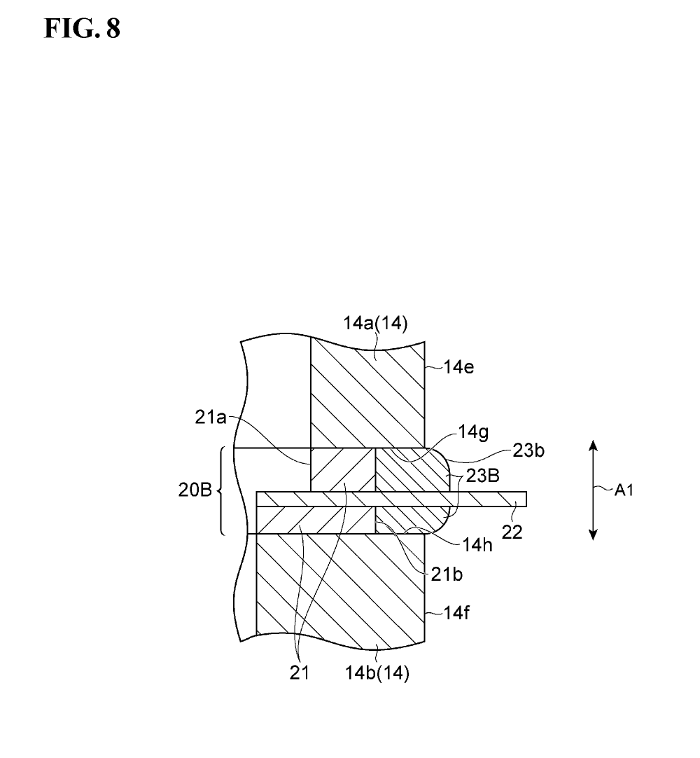

FIG. 8 is an enlarged sectional view of part of a feedthrough 20B that is near an outer surface thereof and peripheral elements included in an optical sensor according to a first modification of the above embodiment. The feedthrough 20B according to the first modification includes a deformation-easing member 23B in replacement of the deformation-easing member 23A according to the above embodiment. The deformation-easing member 23B is made of the same material as the deformation-easing member 23A according to the above embodiment.

The deformation-easing member 23B has an outer surface 23b opposite a surface thereof that is in contact with the insulating member 21. The outer surface 23b projects outward (in a direction away from the insulating member 21) from a surface of a column that is formed of the outer surface 14e of the first member 14a and the outer surface 14f of the second member 14b. Hence, the deformation-easing member 23B according to the first modification covers a longer portion of each of the conductors 22 than the deformation-easing member 23A according to the above embodiment does. Therefore, according to the first modification, the occurrence of local stress in the insulating member 21 and the occurrence of cracks in the insulating member 21 can be suppressed more effectively than in the above embodiment.

### Second Modification

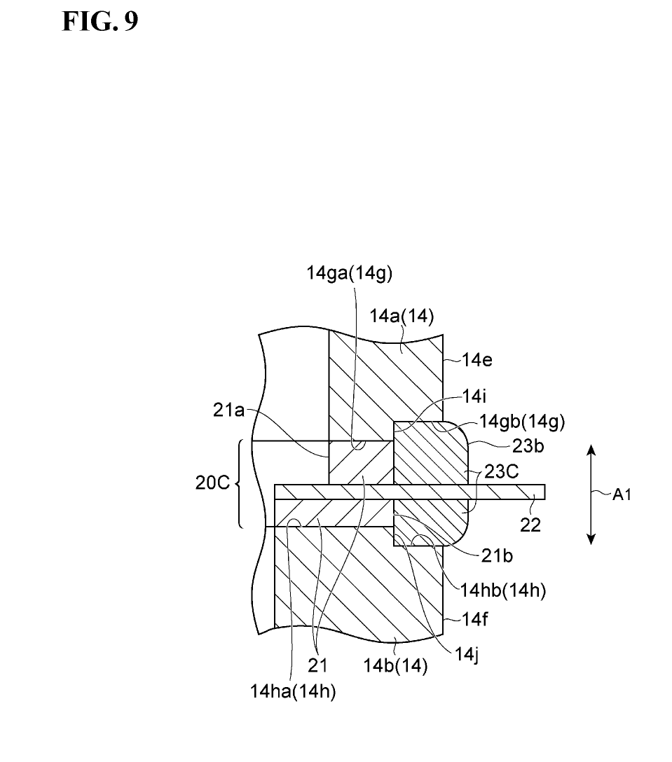

FIG. 9 is an enlarged sectional view of part of a feedthrough 20C that is near an outer surface thereof and peripheral elements included in an optical sensor according to a second modification of the above embodiment. The feedthrough 20C according to the second modification includes a deformation-easing member 23C in replacement of the deformation-easing member 23A according to the above embodiment. The deformation-easing member 23C is made of the same material as the deformation-easing member 23A according to the above embodiment. The deformation-easing member 23C has the outer surface 23b having the same shape as in the first modification.

In the second modification, the end surface 14g of the first member 14a and the end surface 14h of the second member 14b have steps 14i and 14j, respectively. Therefore, an interval W2 in the direction A1 between end surfaces 14gb and 14hb that are on the outer side of the steps 14i and 14j is wider than an interval W1 in the direction A1 between end surfaces 14ga and 14ha that are on the inner side of the steps 14i and 14j. The end surface 14ga and the end surface 14ha are in contact with the insulating member 21. The end surface 14gb and the end surface 14hb are in contact with the deformation-easing member 23C. Hence, the thickness of the deformation-easing member 23C in the direction A1 is larger than the thickness of the insulating member 21 in the direction A1. The deformation-easing member may be shape as in the second modification. Even in that case, the same advantageous effects as in the first modification can be produced.

### Third Modification

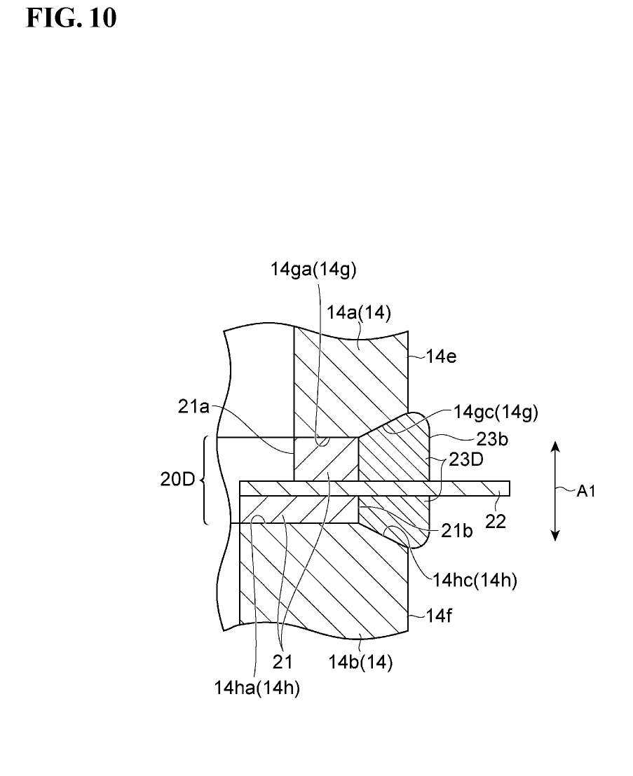

FIG. 10 is an enlarged sectional view of an outer surface of a feedthrough 20D and peripheral elements included in an optical sensor according to a third modification of the above embodiment. The feedthrough 20D according to the third modification includes a deformation-easing member 23D in replacement of the deformation-easing member 23A according to the above embodiment. The deformation-easing member 23D is made of the same material as the deformation-easing member 23A according to the above embodiment. The deformation-easing member 23D has the outer surface 23b having the same shape as in the first modification.

In the third modification, the end surface 14g of the first member 14a includes the end surface 14ga, and an end surface 14gc on the outer side of the end surface 14ga. Likewise, the end surface 14h of the second member 14b includes the end surface 14ha, and an end surface 14hc on the outer side of the end surface 14ha. The end surface 14ga and the end surface 14ha are in contact with the insulating member 21. The end surface 14gc and the end surface 14hc are in contact with the deformation-easing member 23D. The end surfaces 14ga and 14ha extend along a plane perpendicular to the direction A1. Whereas, the end surfaces 14gc and 14hc are inclined with respect to the same plane such that the interval therebetween gradually increases toward the outer side. In other words, the corner formed between the end surface 14g and the outer surface 14e is chamfered, and the corner formed between the end surface 14h and the outer surface 14f is also chamfered. Hence, the thickness of the deformation-easing member 23D in the direction A1 gradually increases toward the outer side. The thickness of the deformation-easing member 23D in a portion thereof that is in contact with the insulating member 21 is the same as the thickness of the insulating member 21 and is thinner than the thickness of a portion of the deformation-easing member 23D that is in contact with the outer surfaces 14e and 14f.

The deformation-easing member may be shape as in the third modification. Even in that case, the same advantageous effects as in the first modification can be produced. Furthermore, since the interval between the end surfaces 14g and 14h that are in contact with the deformation-easing member 23D gradually increases toward the outer side, the material forming the deformation-easing member 23D can be easily placed into the recess. That is, the deformation-easing member 23D can be formed easily.

### Fourth Modification

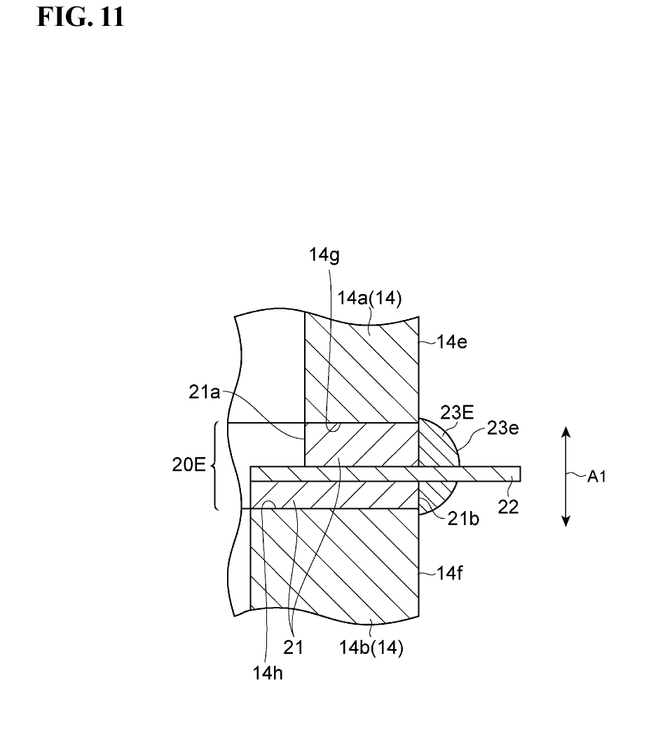

FIG. 11 is an enlarged sectional view of part of a feedthrough 20E that is near an outer surface thereof and peripheral elements included in an optical sensor according to a fourth modification of the above embodiment. The feedthrough 20E according to the fourth modification includes a deformation-easing member 23E in replacement of the deformation-easing member 23A according to the above embodiment. The deformation-easing member 23E is made of the same material as the deformation-easing member 23A according to the above embodiment. In the fourth modification, the outer surface 21b of the insulating member 21 has no recess and is flush with the outer surface 14e of the first member 14a and the outer surface 14f of the second member 14b. The deformation-easing member 23E is provided on a surface of a column that is formed of the outer surface 21b, the outer surface 14e, and the outer surface 14f, with most part of the deformation-easing member 23E being positioned on the outer surface 21b. One end of the deformation-easing member 23E in the direction A1 may be in contact with the outer surface 14e. The other end of the deformation-easing member 23E in the direction A1 may be in contact with the outer surface 14f. The deformation-easing member 23E has an outer surface 23e opposite the surface thereof that is in contact with the insulating member 21. The outer surface 23e has, for example, a semicircular sectional shape in a plane perpendicular to the direction of arrangement of the conductors 22. The deformation-easing member may be shaped as in the fourth modification. Even in that case, the same advantageous effects as in the first modification can be produced.

### Fifth Modification

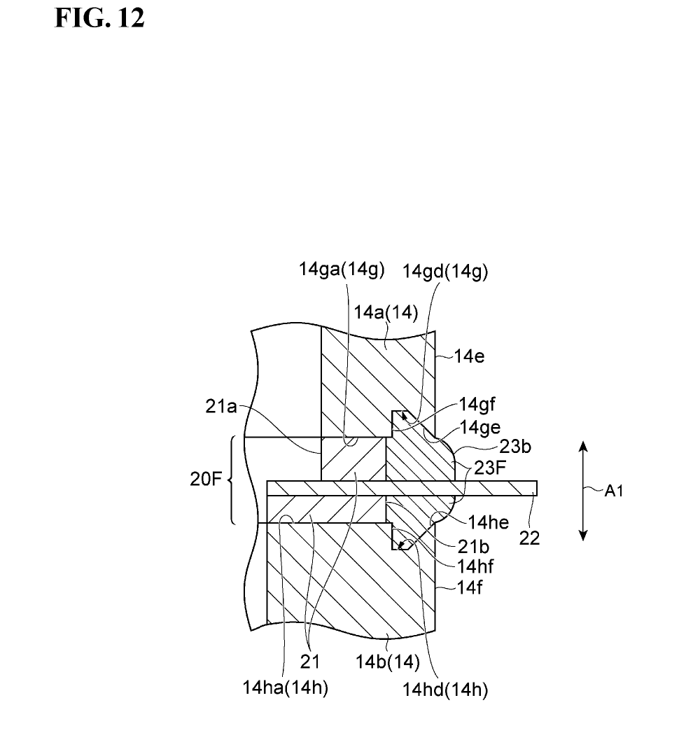

FIG. 12 is an enlarged sectional view of part of a feedthrough 20F that is near an outer surface thereof and peripheral elements included in an optical sensor according to a fifth modification of the above embodiment. The feedthrough 20F according to the fifth modification includes a deformation-easing member 23F in replacement of the deformation-easing member 23A according to the above embodiment. The deformation-easing member 23F is made of the same material as the deformation-easing member 23A according to the above embodiment. Furthermore, the outer surface 23b of the deformation-easing member 23F has the same shape as in the first modification.

The end surface 14g of the first member 14a includes the end surface 14ga, and a recess 14gd provided on the outer side of the end surface 14ga. Likewise, the end surface 14h of the second member 14b includes the end surface 14ha, and a recess 14hd provided on the outer side of the end surface 14ha. The end surfaces 14ga and 14ha are in contact with the insulating member 21. The recesses 14gd and 14hd are in contact with the deformation-easing member 23F. The end surfaces 14ga and 14ha extend along a plane perpendicular to the direction A1. The recesses 14gd and 14hd each have a pair of inner surfaces 14gf and 14ge or 14hf and 14he. The inner surfaces 14gf and 14hf, which are each the inner one of the pair of inner surfaces 14gf and 14ge or 14hf and 14he, extend in the direction A1. The inner surfaces 14ge and 14he, which are each the outer one of the pair of inner surfaces 14gf and 14ge or 14hf and 14he, are inclined with respect to the above plane such that the interval therebetween gradually decreases toward the outer side. Hence, the thickness of the deformation-easing member 23F in the direction A1 is larger than the thickness of the insulating member 21 near a portion that is in contact with the insulating member 21, and is gradually reduced toward the outer side.

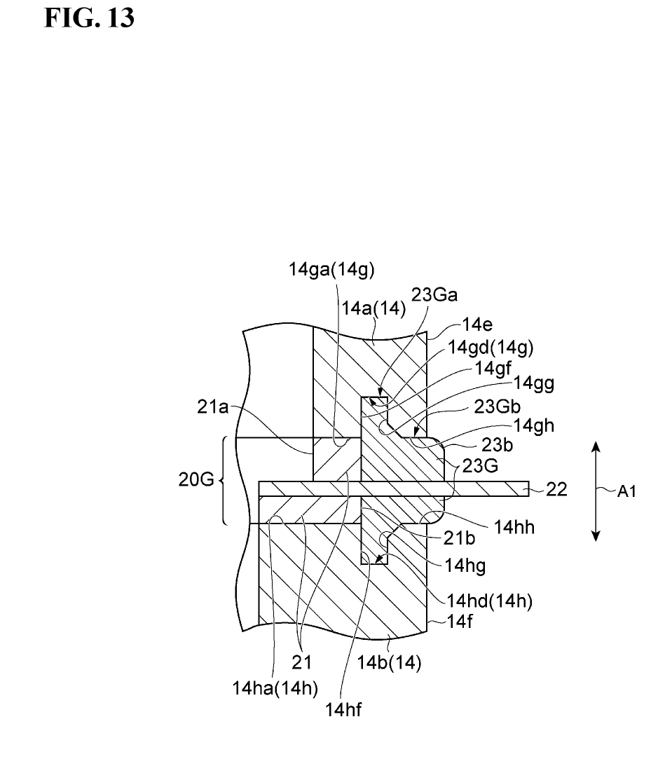

FIG. 13 is an enlarged sectional view of part of a feedthrough 20G that is near an outer surface thereof and peripheral elements according to another example of the fifth modification. The feedthrough 20G according to this example of the fifth modification includes a deformation-easing member 23G in replacement of the deformation-easing member 23A according to the above embodiment. The deformation-easing member 23G is made of the same material as the deformation-easing member 23A according to the above embodiment. The deformation-easing member 23G has the outer surface 23b having the same shape as in the first modification.

In this example, the end surface 14g of the first member 14a includes the end surface 14ga and the recess 14gd provided on the outer side of the end surface 14ga. Furthermore, the end surface 14h of the second member 14b includes the end surface 14ha and the recess 14hd provided on the outer side of the end surface 14ha. The end surfaces 14ga and 14ha are in contact with the insulating member 21. The recesses 14gd and 14hd are in contact with the deformation-easing member 23G. However, in this example, the shapes of the recesses 14gd and 14hd are different from those of the above example of the fifth modification. Specifically, inner surfaces 14gg and 14hg, each being an outer one of a pair of inner surfaces 14gf and 14gg or 14hf and 14hg of a corresponding one of the recesses 14gd and 14hd, extend in the direction A1 and face the respective inner surfaces 14gf and 14hf, each being an inner one of the pair of inner surfaces 14gf and 14gg or 14hf and 14hg. Furthermore, end surfaces 14gh and 14hh extending along the plane perpendicular to the direction A1 are provided on the outer side of the respective recesses 14gd and 14hd. The interval between the end surfaces 14gh and 14hh is equal to the interval between the end surfaces 14ga and 14ha. Hence, the deformation-easing member 23G includes a thick portion 23Ga part of which is in contact with the insulating member 21, and a thin portion 23Gb that is on the outer side of the thick portion 23Ga. The thickness of the thick portion 23Ga in the direction A1 is larger than the thickness of the thin portion 23Gb in the direction A1.

The deformation-easing member may be shaped as illustrated in FIG. 12 or 13. Even in that case, the same advantageous effects as in the first modification can be produced. Furthermore, the volume of the deformation-easing member 23F or 23G near a portion that is in contact with the insulating member 21 is larger than in the above embodiment and in the first modification. Therefore, if any force is applied to the conductors 22, a corresponding stress can be more effectively dispersed over the insulating member 21. Thus, the occurrence of cracks in the insulating member 21 can further be suppressed.

### Sixth Modification

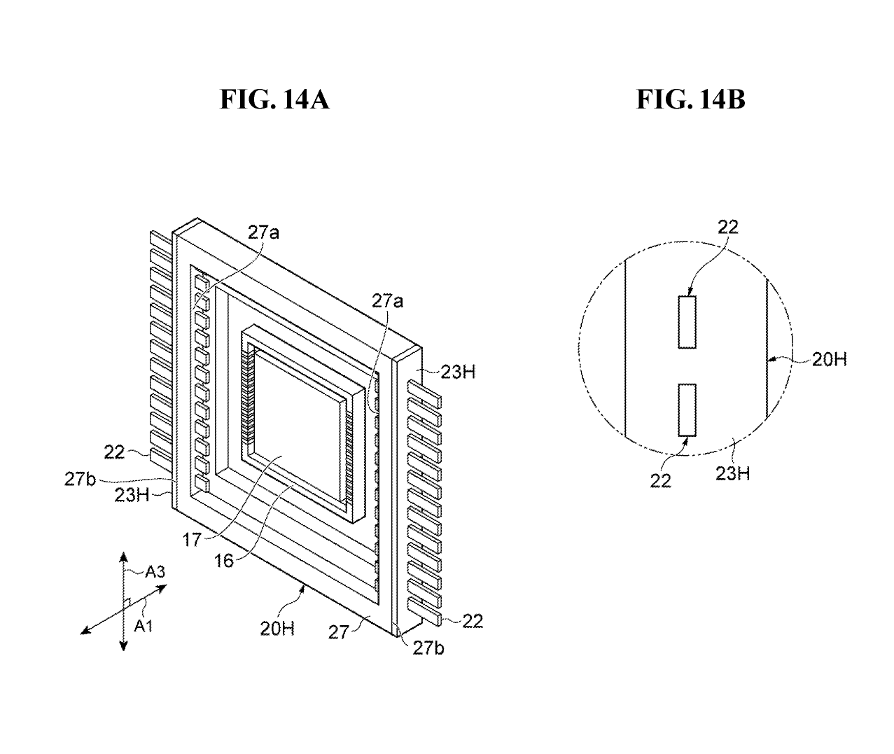

FIG. 14A is an enlarged perspective view of a feedthrough 20H and peripheral elements included in an optical sensor according to a sixth modification of the above embodiment. In FIG. 14A, the entrance window 13 and the frame 18 are not illustrated. FIG. 14B is an enlarged side view of part of the feedthrough 20H.

The feedthrough 20H according to the sixth modification includes an insulating member 27 in replacement of the insulating member 21 included in the feedthrough 20A according to the above embodiment. Unlike the insulating member 21 according to the above embodiment, the insulating member 27 has a quadrilateral shape (a square shape, a rectangular shape, or a trapezoidal shape) when seen in the direction A1 (the incoming direction of the light). The insulating member 21 has inner surfaces 27a each facing the inside of a case that houses the mount 16 and the image sensor device 17, and outer surfaces 27b each facing the outside of the case, thereby separating the inside and the outside of the case from each other. The insulating member 27 is made of an insulating material such as glass, ceramic, or resin, as with the insulating member 21 according to the above embodiment.

The inner surfaces 27a and the outer surfaces 27b each extend linearly in a direction A3 that is orthogonal to the direction A1. That is, while the plurality of conductors 22 according to the above embodiment are arranged side by side in a direction along the periphery of a circular shape, the plurality of conductors 22 according to the sixth modification are arranged side by side in the direction A3 that extends in a flat plane. In the direction A3, the plurality of conductors 22 are arranged at regular intervals.

In the sixth modification, deformation-easing members 23H are provided on the outer surfaces 27b, respectively. The shape of each of the deformation-easing members 23H in a section taken along a plane perpendicular to the direction A3 is the same as in the above embodiment. The deformation-easing member 23H is made of the same material as in the above embodiment. Even in the sixth modification, the same advantageous effects as in the above embodiment can be produced.

The optical sensor and the imaging apparatus according to the present invention are not limited to those described in the above embodiment and the modifications thereof and can be modified in various other ways. For example, features of the above embodiment and modifications may be combined in accordance with desired purposes and advantageous effects. Furthermore, the shape of the deformation-easing member is not limited to those described in the above embodiment and modifications. The deformation-easing member may have any of various other shapes. For example, while the above embodiment and modifications each concern a case where a single deformation-easing member extending in the direction of arrangement of a plurality of conductors covers the plurality of conductors, a plurality of deformation-easing members may be provided for the respective conductors while being arranged at intervals. Furthermore, while the above embodiment and modifications each concern a case where the recess is defined by the insulating member and the hermetically sealed housing, the recess may be provided in the outer surface of the insulating member that is depressed in the longitudinal direction of the conductors. In that case, the recess provided in the insulating member may have the same shape as the recess 14gd or 14hd illustrated in FIG. 12 or 13.

What is claimed is:

1. An optical sensor comprising:
an image sensor device that converts an incident-light image into an electric image signal; and
a case that hermetically houses the image sensor device,
wherein the case has
an entrance window that faces the image sensor device and transmits the incident-light image; and
a feedthrough that includes an insulating member forming part of the case, and a plurality of plate-like conductors each extending through the insulating member and arranged side by side in a predetermined direction, the feedthrough allowing an inside and an outside of the case to be electrically conductive to each other,
wherein the feedthrough further includes
a deformation-easing member that is bonded to the insulating member while covering part of each of the conductors that is positioned on an outer side with respect to the insulating member, the deformation-easing member being easier to deform than the insulating member.

2. The optical sensor according to claim 1,
wherein the insulating member includes at least one of glass and ceramic, and
wherein the deformation-easing member includes resin.

3. The optical sensor according to claim 1,
wherein the deformation-easing member has an insulating characteristic.

4. The optical sensor according to claim 1,
wherein the insulating member forms a bottom surface of a recess provided in an outer surface of the case, and
wherein at least part of the deformation-easing member fills the recess.

5. The optical sensor according to claim 1,
wherein the plurality of conductors each have a rectangular sectional shape.

6. An imaging apparatus comprising:
an optical sensor including an image sensor device that converts an incident-light image into an electric image signal, and a case that hermetically houses the image sensor device;
a circuit board having
wire pads that are each electrically connected to an end of a corresponding one of the plurality of conductors that is positioned on the outside of the case, and
a control circuit that is electrically connected to the wire pads; and
a signal processor that converts an electric signal obtained from the control circuit on the circuit board into an image signal,
wherein the case has
an entrance window that faces the image sensor device and transmits the incident-light image; and
a feedthrough that includes an insulating member forming part of the case, and a plurality of plate-like conductors each extending through the insulating member and arranged side by side in a predetermined direction, the feedthrough allowing an inside and an outside of the case to be electrically conductive to each other,
wherein the feedthrough further includes
a deformation-easing member that is bonded to the insulating member while converting part of each of the conductors that is positioned on an outer side with respect to the insulating member, the deformation-easing member being easier to deform than the insulating member.
